(19) United States
(12) Patent Application Publication
(10) Pub. No.: US 2020/0266615 A1
(43) Pub. Date: Aug. 20, 2020

(54) ENCLOSURE FOR ELECTRICAL COMPONENTS

(71) Applicant: Johnson Controls Technology Company, Auburn Hills, MI (US)

(72) Inventors: Vishal S. Jagtap, Thane (IN); Ravindra B. Salunkhe, Satara (IN); Ketaki S. Vaidya, Pune (IN); Bhushan D. Vichare, Sangli (IN)

(21) Appl. No.: 16/281,698

(22) Filed: Feb. 21, 2019

Related U.S. Application Data
(60) Provisional application No. 62/807,502, filed on Feb. 19, 2019.

(51) Int. Cl. H02G 3/08; H02G 3/10; H02G 3/14; H05K 5/04; H05K 5/02

(52) U.S. Cl. CPC H02G 3/086; H02G 3/10; H05K 5/0239; H05K 5/04; H02G 3/14

(57) ABSTRACT

An enclosure for electrical components for a heating, ventilation, and/or air conditioning (HVAC) system is provided. The enclosure includes an electrical box including a back wall and a wall extending from the back wall to an open front. The enclosure further includes a removable cover including a fifth wall and a lip extending from the fifth wall, wherein the removable cover is configured to be attached to the electrical box to cover the open front and to enclose electrical components within the electrical box by engaging a slot within the wall and the lip extends over a portion of the wall.

### CROSS REFERENCE TO RELATED APPLICATIONS

This application claims priority from and the benefit of U.S. Provisional Application Ser. No. 62/807,502, entitled “ENCLOSURE FOR ELECTRICAL COMPONENTS,” filed Feb. 19, 2019, which is hereby incorporated by reference in its entirety for all purposes.

### BACKGROUND

The present disclosure relates generally to heating, ventilation, and/or air conditioning (HVAC) systems, and specifically, relates to an enclosure for electrical components.

This section is intended to introduce the reader to various aspects of art that may be related to various aspects of the present disclosure, which are described below. This discussion is believed to be helpful in providing the reader with background information to facilitate a better understanding of the various aspects of the present disclosure. Accordingly, it should be understood that these statements are to be read in this light, and not as admissions of prior art.

Environmental control systems are utilized in residential, commercial, and industrial environments to control environmental properties, such as temperature and humidity, for occupants of the respective environments. Certain electrical components (e.g., electrical control components) for the environmental control systems may be enclosed within an electrical box via an access panel or cover. The access panel may not be removable from the electrical box and, thus, limit the space available during servicing of the electrical components within the electrical box. In addition, the access panel may be coupled to the electrical box via multiple components that limit how far or where the access panel may be opened as well as increase the costs of the electrical box assembly.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In one embodiment, an enclosure for electrical components for a heating, ventilation, and/or air conditioning (HVAC) system is provided. The enclosure includes an electrical box including a back wall and a wall extending from the back wall to an open front. The enclosure also includes a removable cover including a fifth wall, a tab extending from the fifth wall, and a lip extending from the fifth wall, wherein the removable cover is configured to be attached to the electrical box to cover the open front and to enclose electrical components within the electrical box by engaging the tab with a slot within the wall and the lip extends over a portion of the wall.

In another embodiment, a HVAC system is provided. The HVAC system includes an electrical box including a back wall and a wall extending from the back wall to an open front, wherein the wall includes a first slot and a second slot. The HVAC system also includes electrical HVAC control components. The HVAC system further includes a removable cover including a fifth wall, wherein the removable cover is configured to be attached to the electrical box to cover the open front and to enclose the electrical HVAC control components within the electrical box by sliding the fifth wall into the first and second slots.

In a further embodiment, an enclosure for electrical components for a HVAC system is provided. The enclosure includes an electrical box including a back wall, a first wall extending from the back wall to an open front and a wall extending from the back wall to the open front. The enclosure further includes a removable cover including a fifth wall and a lip extending from the fifth wall, wherein the removable cover is configured to be attached to the electrical box to cover the open front and to enclose electrical components within the electrical box by engaging a slot within the wall and the lip extends over a portion of the wall.

### DRAWINGS

Various aspects of this disclosure may be better understood upon reading the following detailed description and upon reference to the drawings in which:

FIG. 1 is a perspective view of an enclosure for electrical components of a HVAC system, in accordance with aspects of the present disclosure (e.g., having side slots for receiving an access panel);

FIG. 2 is a perspective view of an electrical box of the enclosure of FIG. 1 with the access panel removed, in accordance with aspects of the present disclosure;

FIG. 3 is a perspective view of the access panel of the enclosure of FIG. 1, in accordance with aspects of the present disclosure;

FIG. 4 is a top view of the electrical box of FIG. 2, in accordance with aspects of the present disclosure;

FIG. 5 is a top view of a portion of the electrical box of FIG. 4, taken within line 5-5 of FIG. 4, in accordance with aspects of the present disclosure;

FIG. 6 is a top view of a portion of the electrical box of FIG. 4, taken within line 6-6 of FIG. 4, in accordance with aspects of the present disclosure;

FIG. 7 is a perspective schematic view of the enclosure of FIG. 1 illustrating the assembly of the enclosure to enclose electrical components, in accordance with aspects of the present disclosure;

FIG. 8 is a perspective view of a portion of the electrical box of FIG. 7 having a fastener, taken within line 8-8 of FIG. 7, in accordance with aspects of the present disclosure;

FIG. 9 is a perspective view of an enclosure for electrical components of a HVAC system, in accordance with aspects of the present disclosure (e.g., having bottom slots for receiving an access panel);

FIG. 10 is a perspective view of an electrical box of the enclosure of FIG. 9 with the access panel removed, in accordance with aspects of the present disclosure;

FIG. 11 is a perspective view of the access panel of the enclosure of FIG. 9, in accordance with aspects of the present disclosure;

FIG. 12 is a perspective schematic view of the enclosure of FIG. 9 illustrating the assembly of the enclosure to enclose electrical components, in accordance with aspects of the present disclosure;

FIG. 13 is a perspective view of a fastener (e.g., knob) for an enclosure for electrical components;

FIG. 14 is a perspective view of a fastener (e.g., screw) for an enclosure for electrical components; and

FIG. 15 is a perspective view of a fastener (e.g., screw) for an enclosure for electrical components.

### DETAILED DESCRIPTION

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

The present disclosure is directed to an enclosure (e.g., electrical box assembly) for electrical components (e.g., control components) of a heating, ventilation, and/or air conditioning (HVAC) system. For example, the enclosure may include an electrical box and an access panel or cover that when coupled to the electrical box encloses the electrical components within the electrical box. The cover may be removable to provide greater access to the electrical components within the electrical box (e.g., during servicing).

The configuration of the enclosure may vary based on the location of the enclosure. In addition, the number of components to couple and/or secure the cover to the electrical box are minimal compared to typical enclosures for electrical components. For example, in certain embodiments, the electrical box includes one or more slots to receive the cover. In certain embodiments, a bottom wall extending from a back wall of the electrical box may include one or more slots to receive one or more respective tabs extending from the cover. In other embodiments, side walls extending from the back wall of the electrical box may include bent extensions that define slots to receive the cover. The cover may also include a lip that partially extends over a portion of a top wall extending from the back wall of the electrical box. The cover may be secured to the electrical box via a fastener (e.g., knob, screw, latch, etc.) that extends through both the lip of the cover and the top wall of the electrical box. The utilization of fewer components to secure the cover to the electrical box enables rapid coupling or removal of the cover from the electrical box. In addition, the utilization of fewer components reduces the cost of manufacturing the enclosure.

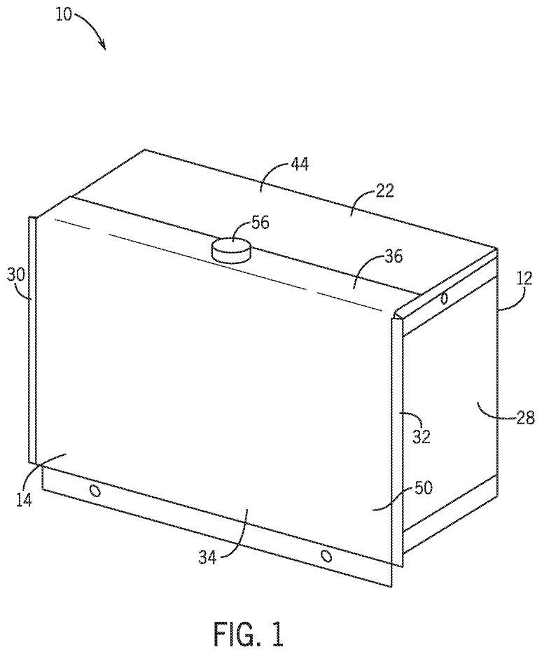

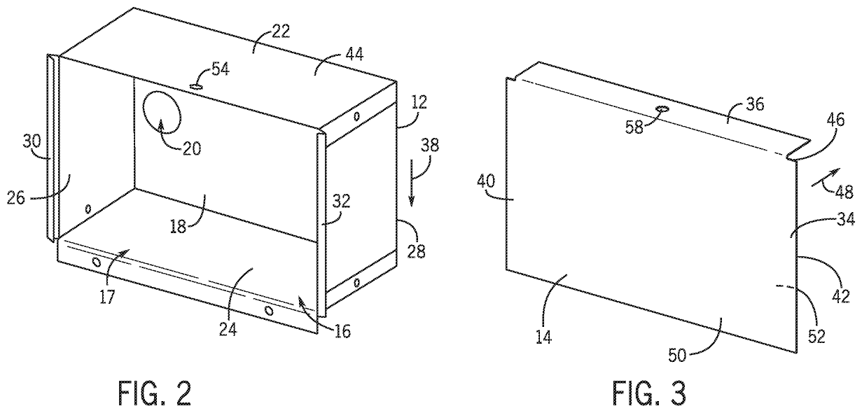

Turning now to the drawings, FIGS. 1-3 illustrate an embodiment of an enclosure 10 for electrical components of a HVAC system. The enclosure 10 includes an electrical box 12 and an access panel or cover 14. In certain embodiments, the electrical box 12 and the cover 14 may be made of a metal (e.g., sheet metal). When the cover 14 is coupled or secured to the electrical box 12 electrical components (e.g., control components) are enclosed with the enclosure 10. The cover 14 is removable from the electrical box 12 to provide greater access to the interior 16 of the electrical box 12 (e.g., during servicing) via an open front 17.

The electrical box 12 includes a wall 18 (e.g., back wall). The back wall 18 may include one or more openings (e.g., opening 20) for electrical components to extend into the electrical box 12. Wall 22 (e.g., top wall) and wall 24 (bottom wall) extend away from the back wall 18 toward the open front 17. Wall 26 (e.g., side wall) and wall 28 (e.g., side wall) extend between the walls 22, 24 and away from the back wall 18 toward the open front 17. In certain embodiments, a circular wall may extend from the back wall 18. As will be described in greater detail below, the walls 26, 28 each include a respective extension 30, 32. The extensions 30, 32 are each bent to define a respective slot. The slots extend between the wall 22 and the wall 24.

The cover 14 includes a wall 34 and a lip 36. The wall 34 of the cover 14 is configured to be slid within the slots defined by the extensions 30, 32 in a direction 38 (e.g., vertically) from the wall 22 toward the wall 24 to couple or secure the cover 14 to the electrical box 12 to enclose the electrical components within the enclosure 10. In particular, opposite edges 40 and 42 (e.g., side edges) of the wall 34 of the cover 14 are slid within the slots defined by the extensions 30, 32. The wall 34 of the cover 14 slides into the slots defined by the extensions 30, 32 until the lip 36 contacts an outer surface 44 (e.g., top surface) of the wall 22. The lip 36 extends from an edge 46 (e.g., top edge) that extends between the edges 40, 42. The lip 36 may extend along an entire length of the edge 46 or only a portion of the length of the edge 46. The lip 36 extends in a direction 48 from surface 50 (e.g., outer surface) to surface 52 (e.g., inner surface) of the wall 34. When the cover 14 is coupled or secured to the electrical box 12, the lip 36 only partially extends over the outer surface 44 of the wall 22. In certain embodiments, the lip 36 may extend over the entire outer surface 44 of the wall 22.

The wall 22 includes an opening 54 adjacent the open front 17 of the electrical box 12. In certain embodiments, a nut (e.g., rivet nut) may be disposed within the opening 54 to receive a fastener 56 to secure the cover 14 to the electrical box 12. The lip 36 also includes an opening 58 that is configured to be vertically aligned with the opening 54 when the cover 14 is coupled to the electrical box 12. In certain embodiments, the fastener 56 is configured to extend through the openings 54, 56 to secure the cover 14 to the electrical box 12. As described in greater detail below, the fastener 56 may include a knob (e.g., as illustrated in FIG. 1), a screw, a latch, or another type of fastener.

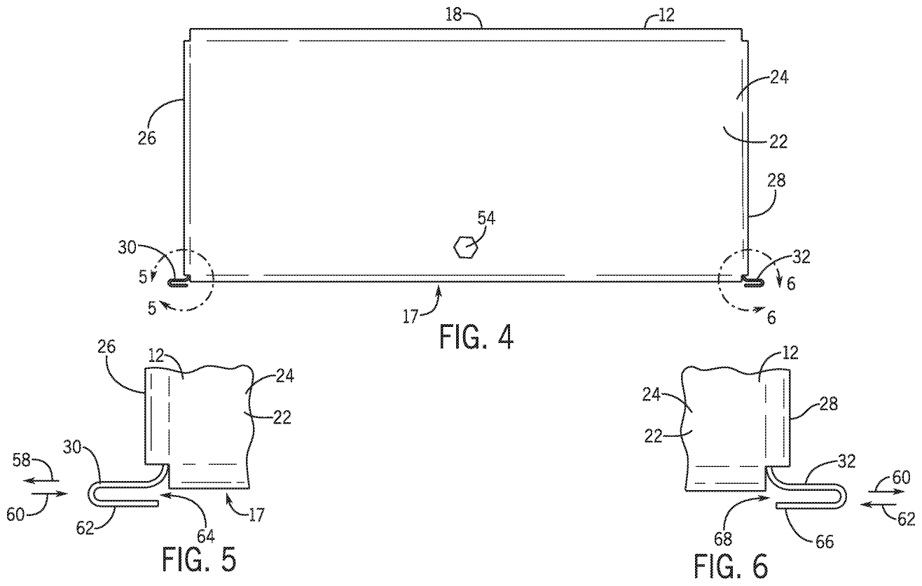

FIGS. 4-6 illustrate the slots defined by the extensions 30, 32 of the electrical box 12. Extension 30 extends in a direction 58 away from the wall 26 and then in a direction 60 toward the wall 26 until it terminates in a free end or edge 62 to define or form slot 64. Slot 64 is configured to receive the edge 40 of the wall 34 of the cover 12. Extension 32 extends in the direction 60 away from the wall 28 and then in the direction 58 toward the wall 28 until it terminates in a free end or edge 66 to define or form slot 68. Slot 64 is configured to receive the edge 42 of the wall 34 of the cover 12.

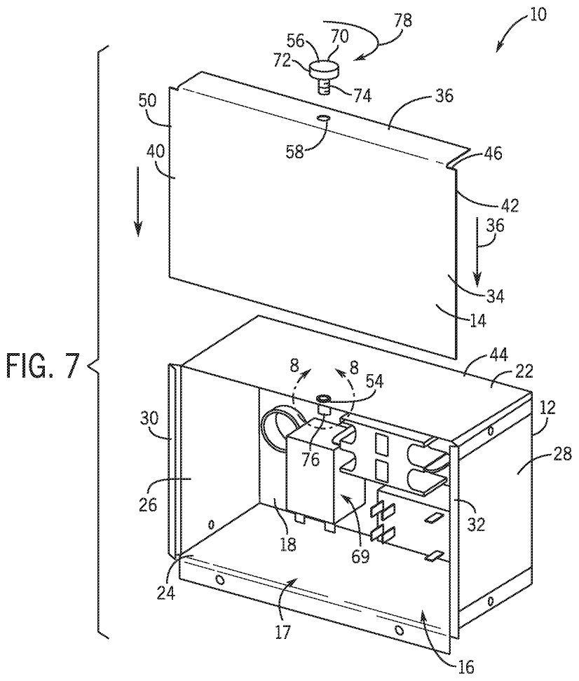

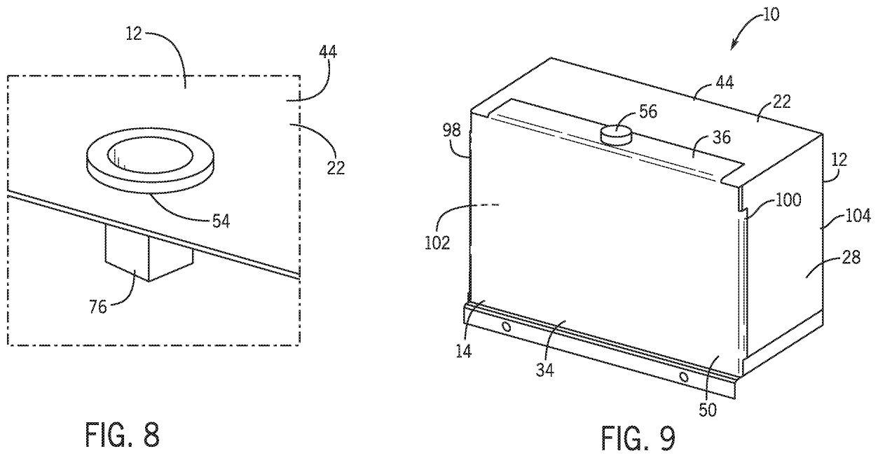

FIG. 7 illustrates the assembly of the enclosure 10 to secure electrical components 69 within the enclosure 10. First, the wall 34 of the cover 14 is inserted into and then slid within the slots 62, 68 (see FIGS. 4-6) in the direction 38 from the wall 22 to the wall 24 until the lip 36 of the cover 14 abuts or contacts the surface 44 of the wall 22. Second, the fastener 56 is inserted through the respective openings 58, 54 of the lip 36 and the wall 22. As depicted in FIG. 7, the fastener 56 is a knob 70 that includes a head portion 72 and a threaded portion 74. As depicted in FIGS. 7 and 8, a nut 76 (e.g., rivet nut) is disposed within the opening 54 of the wall 22. In certain embodiments, the nut 76 is crimped to the electrical box 12 within the opening 54. The nut 76 includes an internal threaded portion to receive the threaded portion 74 of the knob 70. Rotation 78 of the head portion 72 of the knob 70 screws the knob within the nut 76 to enable securing of the cover 14 to the electrical box 12. In certain embodiments, a screw may be utilized instead of the knob 72. In other embodiments, a latch may be utilized instead of the screw or knob 72 and the nut 76 to secure the cover 14 to the electrical box 12.

FIGS. 9-11 illustrate another embodiment of the enclosure 10 for electrical components of a HVAC system. The enclosure 10 includes the electrical box 12 and the access panel or cover 14. In certain embodiments, the electrical box 12 and the cover 14 may be made of a metal (e.g., sheet metal). When the cover 14 is coupled or secured to the electrical box 12 electrical components (e.g., control components) are enclosed with the enclosure 10. The cover 14 is removable from the electrical box 12 to provide greater access to the interior 16 of the electrical box 12 (e.g., during servicing) via the open front 17.

The electrical box 12 includes the wall 18 (e.g., back wall). The back wall 18 may include one or more openings (e.g., opening 20) for electrical components to extend into the electrical box 12. Wall 22 (e.g., top wall) and wall 24 (bottom wall) extend away from the back wall 18 toward the open front 17. Wall 26 (e.g., side wall) and wall 28 (e.g., side wall) extend between the walls 22, 24 and away from the back wall 18 toward the open front 17.

The cover 14 includes the wall 34 and the lip 36. The lip 36 extends from the edge 46 (e.g., top edge) that extends between the edges 40, 42. The lip 36 may extend along an entire length of the edge 46 or only a portion of the length of the edge 46. The lip 36 extends in the direction 48 from surface 50 (e.g., outer surface) to surface 52 (e.g., inner surface) of the wall 34. When the cover 14 is coupled or secured to the electrical box 12, the lip 36 only partially extends over the outer surface 44 of the wall 22. In certain embodiments, the lip 36 may extend over the entire outer surface 44 of the wall 22.

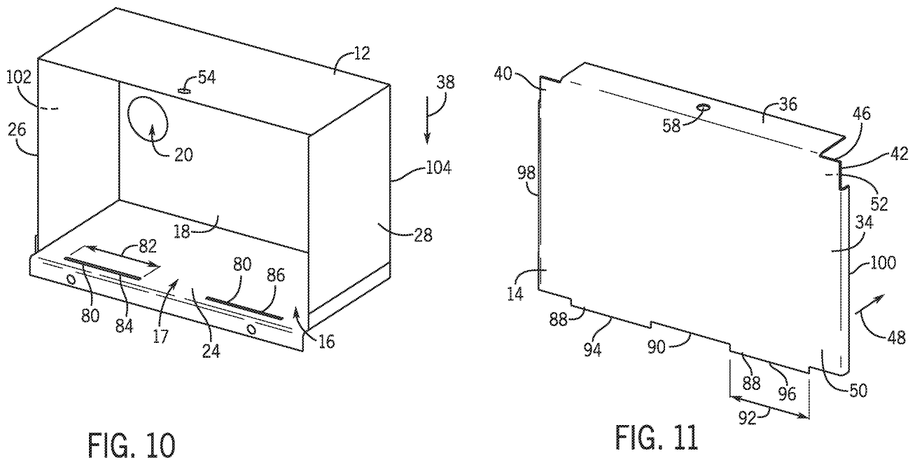

The wall 24 includes one or more slots 80 adjacent the open front 17. The number of slots 80 may vary (e.g., 1, 2, 3, 4, 5, or more slots 80). A length 82 of the slots 80 may vary between electrical boxes 12 or within the same electrical box. A location of the slots 80 may vary. For example, in certain embodiments, one or more slots 80 may be adjacent the side walls 26, 28. In other embodiments, one or more slots 80 may be centrally located between the side walls 26, 28. As depicted in FIG. 10, the wall 24 include two slots 84, 86. The slot 84 is more adjacent to the wall 26, while the slot 86 is more adjacent to the wall 28.

The wall 34 of the cover 14 includes one or more tabs 88 (e.g., protrusions) extending away from an edge 90 (e.g., bottom edge) of the wall 34 in the direction 38. The tabs 88 are configured to be inserted (e.g., in the direction 38) within the slots 80 on the wall 24 when the cover 14 is coupled to or secured to the electrical box 10. The number of tabs 88 may vary (e.g., 1, 2, 3, 4, 5, or more tabs 88). The number of tabs 88 corresponds to the number of slots 80. A length 92 of the tabs 88 may vary between electrical boxes 12 or within the same electrical box. The length of each tab 88 is less than the length 82 of the respective slot 80 that the tab 88 is inserted into when coupling the cover 14 to the electrical box 12. A location of tabs 88 may vary. For example, in certain embodiments, one or more tabs 88 may be adjacent the edges 40, 42. In other embodiments, one or more tabs 88 may be centrally located between the edges 40, 42. As depicted in FIG. 11, the wall 34 include two tabs 94, 96. The tab 94 is more adjacent to the edge 40, while the tab 96 is more adjacent to the edge 42.

The wall 34 of the cover 14 also includes lips 98, 100. Lips 98, 100 extend from the respective edges 40, 42. The lips 98, 100 may extend along an entire length of the respective edges 40, 42 or only a portion of the length of the respective edges 40, 42. The lips 98, 100 extend in the direction 48 from surface 50 (e.g., outer surface) to surface 52 (e.g., inner surface) of the wall 34. When the cover 14 is coupled or secured to the electrical box 12, the lips 98, 100 only partially extend over respective outer surfaces 102, 104 of the walls 26, 28. In certain embodiments, the lips 98, 100 may extend over the entire respective outer surfaces 102, 104 of the walls 26, 28.

The wall 22 includes the opening 54 adjacent the open front 17 of the electrical box 12. In certain embodiments, a nut (e.g., rivet nut) may be disposed within the opening 54 to receive the fastener 56 to secure the cover 14 to the electrical box 12. The lip 36 also includes the opening 58 that is configured to be vertically aligned with the opening 54 when the cover 14 is coupled to the electrical box 12. In certain embodiments, the fastener 56 is configured to extend through the openings 54, 56 to secure the cover 14 to the electrical box 12. As described in greater detail below, the fastener 56 may include a knob (e.g., as illustrated in FIG. 10), a screw, a latch, or another type of fastener.

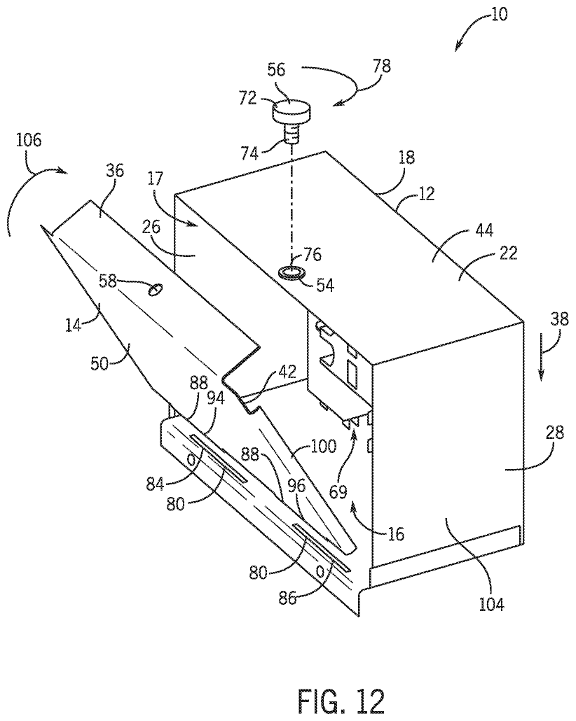

FIG. 12 illustrates the assembly of the enclosure 10 to secure electrical components 69 within the enclosure 10. First, the tabs 88 of the wall 34 of the cover 14 are inserted into the respective slots 80 of the wall 24 in the direction 38. During the insertion of the tabs 88 into the slots 80, the wall 34 of the cover 14 may be perpendicular relative to the wall 24 or angled (e.g., at an obtuse angle) relative to the wall 24. Second, if inserted into slots 80 at an angle, the wall 34 of the cover 14 is swung toward the open front 17 of the electrical box 12 (as indicated by arrow 106) until the lip 36 of the cover 14 abuts or contacts the surface 44 of the wall 22. The lips 98, 100 are also disposed over the surfaces 102, 104 of the walls 26, 28. Third, the fastener 56 is inserted through the respective openings 58, 54 of the lip 36 and the wall 22. As depicted in FIG. 9, the fastener 56 is a knob 70 that includes the head portion 72 and the threaded portion 74. As shown in FIG. 8, the nut 76 (e.g., rivet nut) is disposed within the opening 54 of the wall 22. The nut 76 includes the internal threaded portion to receive the threaded portion 74 of the knob 70. Rotation 78 of the head portion 72 of the knob 70 screws the knob within the nut 76 to enable securing of the cover 14 to the electrical box 12. In certain embodiments, a screw may be utilized instead of the knob 72. In other embodiments, a latch may be utilized instead of the screw or knob 72 and the nut 76 to secure the cover 14 to the electrical box 12.

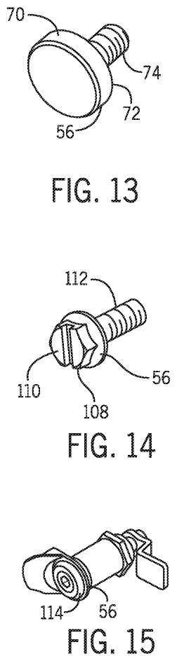

FIGS. 13-15 illustrate embodiments of the fastener 56 that may be utilized to secure the cover 14 to the electrical box 12. FIG. 13 illustrates the knob 70. The knob 70 includes the head portion 72 and the threaded portion 74 as described above. The knob 70 may be fastened to the rivet nut 76 by hand. FIG. 14 illustrates a screw 108. The screw 108 includes a head portion 110 and a threaded portion 112. The screw 108 engages the rivet nut 76 in a similar manner to the knob 70 described above. Unlike the knob 70, a tool (e.g., screw driver) may be utilized to fully tighten the screw 108 within the rivet nut 76. FIG. 15 illustrates a latch 114 that may be utilized instead of the knob 70 or screw 108 and the rivet nut 76. Similar to the screw 108, a tool may be utilized to fasten the latch 114.

The enclosure of the present disclosure may provide one or more technical effects useful in the enclosing of electrical components of a HVAC system. For example, the enclosure may include an electrical box that is coupled to a removable cover. Removal of the cover provides more space and access to the electrical components within the electrical box. In addition, the enclosure includes fewer components to enable the enclosure of the electrical components. In addition, the number of components to couple and/or secure the cover to the electrical box are minimal compared to typical enclosures for electrical components. For example, in certain embodiments, the electrical box includes one or more slots to receive the cover. In certain embodiments, a bottom wall extending from a back wall of the electrical box may include one or more slots to receive one or more respective tabs extending from the cover. In other embodiments, side walls extending from the back wall of the electrical box may include bent extensions that define slots to receive the cover. The cover may also include a lip that partially extends over a portion of a top wall extending from the back wall of the electrical box. The cover may be secured to the electrical box via a fastener (e.g., knob, screw, latch, etc.) that extends through both the lip of the cover and the top wall of the electrical box. The utilization of fewer components to secure the cover to the electrical box enables rapid coupling or removal of the cover from the electrical box. In addition, the utilization of fewer components reduces the cost of manufacturing the enclosure. The technical effects and technical problems in the specification are examples and are not limiting. It should be noted that the embodiments described in the specification may have other technical effects and can solve other technical problems.

While only certain features and embodiments of the disclosure have been illustrated and described, many modifications and changes may occur to those skilled in the art, such as variations in sizes, dimensions, structures, shapes and proportions of the various elements, values of parameters, including temperatures and pressures, mounting arrangements, use of materials, colors, orientations, and so forth without materially departing from the novel teachings and advantages of the subject matter recited in the claims. The order or sequence of any process or method steps may be varied or re-sequenced according to alternative embodiments. It is, therefore, to be understood that the appended claims are intended to cover all such modifications and changes as fall within the true spirit of the disclosure. Furthermore, in an effort to provide a concise description of the exemplary embodiments, all features of an actual implementation may not have been described, such as those unrelated to the presently contemplated best mode of carrying out the disclosure, or those unrelated to enabling the claimed disclosure. It should be appreciated that in the development of any such actual implementation, as in any engineering or design project, numerous implementation specific decisions may be made. Such a development effort might be complex and time consuming, but would nevertheless be a routine undertaking of design, fabrication, and manufacture for those of ordinary skill having the benefit of this disclosure, without undue experimentation.

1. An enclosure for electrical components for a heating, ventilation, and/or air conditioning (HVAC) system, comprising:
an electrical box including a back wall and a wall extending from the back wall to an open front; and
a removable cover including a fifth wall, a tab extending from the fifth wall, and a lip extending from the fifth wall, wherein the removable cover is configured to be attached to the electrical box to cover the open front and to enclose electrical components within the electrical box by engaging the tab with a slot within the wall wall and the lip extends over a portion of the wall.

2. The enclosure of claim 1, wherein the wall comprises a first wall extending from the back wall to an open front, a second wall extending from the back wall to the open front, and a third wall and a fourth wall both extending between the first wall and the second wall and extending from the back wall to the open front, and wherein the removable cover is configured to be attached to the electrical box to cover the open front and to enclose electrical components within the electrical box by engaging the tab with the slot within the second wall and the lip extends over the portion of the first wall, the third wall, or the fourth wall.

3. The enclosure of claim 2, wherein the removable cover is configured to be inserted in the slot in a direction from the first wall toward the second wall.

4. The enclosure of claim 2, wherein the first wall is a top wall and the second wall is a bottom wall.

5. The enclosure of claim 2, wherein the lips extends over a portion of the first wall.

6. The enclosure of claim 2, wherein the removable cover is configured to be secured to the electrical box via a fastener that extends through the first wall and the lip.

7. The enclosure of claim 6, wherein the fastener comprises a screw, knob, or latch.

8. The enclosure of claim 6, comprising a rivet nut coupled to the first wall and configured to receive the fastener.

9. The enclosure of claim 2, wherein second wall comprises a plurality of slots and the removable cover comprises a plurality of tabs each configured to be inserted within a respective slot of the plurality of slots.

10. The enclosure of claim 2, wherein the lip comprises a first lip and a second lip extending from a perimeter portion of the fifth wall and the first and second lips are configured to partially extend over the third and fourth walls, respectively, of the electrical box when the removable cover is attached to the electrical box.

11. A heating, ventilation, and/or air conditioning (HVAC) system, comprising:
an electrical box including a back wall and a wall extending from the back wall to an open front, wherein the wall includes a first slot and a second slot;
electrical HVAC control components; and
a removable cover including a fifth wall, wherein the removable cover is configured to be attached to the electrical box to cover the open front and to enclose the electrical HVAC control components within the electrical box by sliding the fifth wall into the first and second slots.

12. The HVAC system of claim 1, wherein the wall comprises a first wall extending from the back wall to an open front, a second wall extending from the back wall to the open front, and a third wall and a fourth wall both extending between the first wall and the second wall and extending from the back wall to the open front, and wherein the third wall includes the first slot and the fourth wall includes the second slot.

13. The HVAC system of claim 12, wherein the first wall is a top wall and the second wall is a bottom wall.

14. The HVAC system of claim 13, wherein fifth wall comprises a lip extending from the fifth wall, and the lip is configured to extend over a portion of the first wall when the removable cover is attached to the electrical box.

15. The HVAC system of claim 14, wherein the fifth wall is configured to be slid within the first slot and the second slot in a direction from the first wall toward the second wall until the lip abuts the first wall.

16. The HVAC system of claim 14, wherein the removable cover is configured to be secured to the electrical box via a fastener that extends through the first wall and the lip.

17. The HVAC system of claim 16, wherein the fastener comprises a screw, knob, or latch.

18. The HVAC system of claim 16, comprising a rivet nut coupled to the first wall and configured to receive the fastener.

19. The HVAC system of claim 12, wherein the first wall and the second wall respectively comprise a first bent extension and a second bent extension that respectively define the first slot and the second slot.

20. An enclosure for electrical components for a heating, ventilation, and/or air conditioning (HVAC) system, comprising:
an electrical box including a back wall and a wall extending from the back wall to an open front; and
a removable cover including a fifth wall and and a lip extending from the fifth wall, wherein the removable cover is configured to be attached to the electrical box to cover the open front and to enclose electrical components within the electrical box by engaging a slot within the wall and the lip extends over a portion of the wall.

21. The enclosure of claim 20, wherein the wall comprises a first wall extending from the back wall to an open front, a second wall extending from the back wall to the open front, and a third wall and a fourth wall both extending between the first wall and the second wall and extending from the back wall to the open front.

22. The enclosure of claim 21, wherein the removable cover is configured to be attached to the electrical box to cover the open front and to enclose electrical components within the electrical box by engaging the slot within the second, third, or fourth wall and the lip extends over the portion of the first wall.

23. The enclosure of claim 21, wherein second wall comprises a plurality of slots and the removable cover comprises a plurality of tabs each configured to be inserted within a respective slot of the plurality of slots.

24. The enclosure of claim 21, wherein the slot comprises a first slot and a second slot, and wherein the first wall and the second wall respectively comprise a first bent extension and a second bent extension that respectively define the first slot and the second slot.

25. The enclosure of claim 21, wherein the removable cover is configured to be inserted in the slot in a direction from the first wall toward the second wall.

26. The enclosure of claim 21, wherein the first wall is a top wall and the second wall is a bottom wall.

27. The enclosure of claim 20, wherein the removable cover is configured to be secured to the electrical box via a fastener that extends through the wall and the lip.
